(19) United States
(12) Patent Application Publication
(10) Pub. No.: US 2012/0140556 A1
(43) Pub. Date: Jun. 7, 2012

(54) METHOD OF OPERATING FLASH MEMORY

(75) Inventors: PO-CHOU CHEN, Hsinchu (TW); Tao-Cheng Lu, Hsinchu (TW); Yao-Wen Chang, Hsinchu (TW); I-Chen Yang, Hsinchu (TW)

(73) Assignee: MACRONIX International Co., LTD., Hsinchu (TW)

(21) Appl. No.: 12/961,847

(22) Filed: Dec. 7, 2010

(51) Int. Cl. G11C 16/04; G11C 16/12

(52) U.S. Cl. 365/185.02; 365/185.03

(57) ABSTRACT

A method of operating a flash memory is described. When a first storage site has 2ⁿ program levels, the numbers of program levels of the storage sites neighboring to the first storage site are set to be 2ⁿ⁻¹. When a second storage site has 2ⁿ⁻¹ program levels, the numbers of program levels of the storage sites neighboring to the second storage site are set to be 2ⁿ. Each program level corresponds to a different Vt-distribution.

### BACKGROUND OF THE INVENTION

1. Field of the Invention

The invention relates to a method of operating a memory, and more particularly to a method of operating a flash memory.

2. Description of Related Art

Non-volatile memory (NVM) is the hottest memory technology now. In a type of NVM, an oxide-nitride-oxide (ONO) structure with charge-trapping effect is adopted instead of the floating gate structure of the traditional cells. Being easily fabricated and having high density, the NVM with the ONO structure attracts much attention and study from various circles. Such NVM is also referred to as charge-trapping flash memory, wherein the ONO structure within each memory cell can store charges. The charges stored affect the threshold voltage (Vt) of the memory cell and the Vt is sensed to determine the data value.

Currently, the multi-level cell (MLC) capable of storing more than two states has been developed to increase the storage density. The term “multi-level” means that the charging includes multiple potential levels, i.e., multiple Vt values. Thereby, the value of more than one bits can be stored in each memory cell, as shown in FIG. 1.

FIG. 1 shows a plurality of word lines including WL0-WL2, a plurality of bit lines including BL1-BL2 and a plurality of memory cells 100 of a memory in the prior art. Each memory cell 100 corresponds to one word line and two bit lines. However, along with the decrease in the memory size, when two storage sites 100a and 100b each have four program levels, a cross-interaction 102 may occur between them. That is, for example, the electric field established by the charges in the storage site 100a affects the operation of the neighboring storage site 100b, which can be called a 2^{nd}-bit effect.

During the programming of a memory cell 10, because a programming voltage is applied to the corresponding word line WL1, the storage site 100a suffers from a program disturbance 104 from the left bit line BL1. Further, as the cell size is reduced to 75 nm and the distance between the word lines is shortened, the storage sites 100a and 100b also suffer from a word line interference 106 from the storage sites of the two cells 10 at the front side and the back side respectively.

FIG. 2 shows a Vt-distribution diagram of the storage site 100a affected by the aforementioned parasitic effects, wherein the four program levels correspond to four different Vt-distributions. The four storage states 200, 202, 204 and 206 have four different Vt-distributions separated from each other. When the device size gets smaller, the 2^{nd}-bit effect generated by the charges stored in the neighboring cell leads to a larger Vt-distribution 208 for the storage state 200 with no charge. The Vt-distribution is further broadened to be the distribution 210 due to the program disturbance, and even further broadened to be the distribution 212 due to the word line interference as the distance between the word lines is decreased. As a result, the storage state 200 cannot be distinguished from the threshold state 202, so each cell in the memory can have 3 program levels at most and can be operated as one bit only.

### SUMMARY OF THE INVENTION

Accordingly, this invention provides a method of operating a flash memory, by which the memory is prevented from being affected by the 2^{nd} bit effect, program disturbance and word line interference.

The invention also provides a method of operating a flash memory, which can increase the storage density by 1.5 times as compared to the conventional single-level cell (SLC) or multi-level cell (MLC) memory.

The method of operating a flash memory of this invention is applied to a flash memory with a plurality of storage sites arranged in an array. When a first storage site among the storage sites has 2ⁿ program levels, the numbers of program levels of the storage sites neighboring to the first storage site are set to be 2ⁿ⁻¹. When a second storage site among the storage sites has 2ⁿ⁻¹ program levels, the numbers of program levels of the storage sites neighboring to the second storage site are set to be 2ⁿ. Each of the program levels corresponds to a different Vt-distribution.

According to an embodiment of this invention, the flash memory may include a virtual ground memory array or NAND flash memory. The flash memory may include charge-trapping memory cells or floating-gate memory cells. The storage sites are all multi-level cells (MLC), or include multi-level cells (MLC) and single-level cells (SLC). In addition, n may be a positive integer not less than 2, such as 2, 3 or 4.

The operation method of this invention is also applied to a flash memory that includes a plurality of word lines, a plurality of bit lines, and a plurality of memory cells each corresponding to one word line and a pair of bit lines. The method includes: setting the numbers of program levels of the storage sites of the cells corresponding to the same word line to be 2ⁿ and 2ⁿ⁻¹ alternately, and setting the numbers of program levels of the storage sites of the memory cells corresponding to the same bit line to be 2ⁿ and 2ⁿ⁻¹ alternately. Each program level corresponds to a different Vt-distribution.

According to an embodiment of the invention, the flash memory may include a virtual ground memory array. The memory cells may include charge-trapping memory cells or floating-gate memory cells. The storage sites are all MLCs, or include MLCs and SLCs. In addition, n may be a positive integer not less than 2, such as 2, 3 or 4.

Accordingly, in the operation method of the invention, each storage site having 2ⁿ⁻¹ program levels is surrounded by storage sites having 2ⁿ program levels, and each storage site having 2ⁿ program levels is surrounded by storage sites having 2ⁿ⁻¹ program levels. Thereby, the storage density of the flash memory is higher than that of SLC or MLC memory. Further, since the parasitic effects can be reduced, the Vt-distributions of the program levels are maintained separate.

In order to make the aforementioned and other features and advantages of the invention more comprehensible, several embodiments accompanied with figures are described in detail below.

### BRIEF DESCRIPTION OF THE DRAWINGS

FIG. 1 illustrates a top view of a conventional charge-trapping flash memory.

FIG. 2 illustrates a Vt-distribution diagram of a memory cell affected by the parasitic effects in the prior art.

FIG. 3 illustrates a top view of a flash memory according to an embodiment of the invention.

FIG. 4 depicts a Vt-distribution diagram of a storage site with 2ⁿ program levels in FIG. 3 when n equals 2 according to an embodiment of the invention.

FIG. 5 illustrates a top view of a flash memory according to another embodiment of the invention.

FIG. 6 illustrates a top view of a floating-gate flash memory according to still another embodiment of the invention.

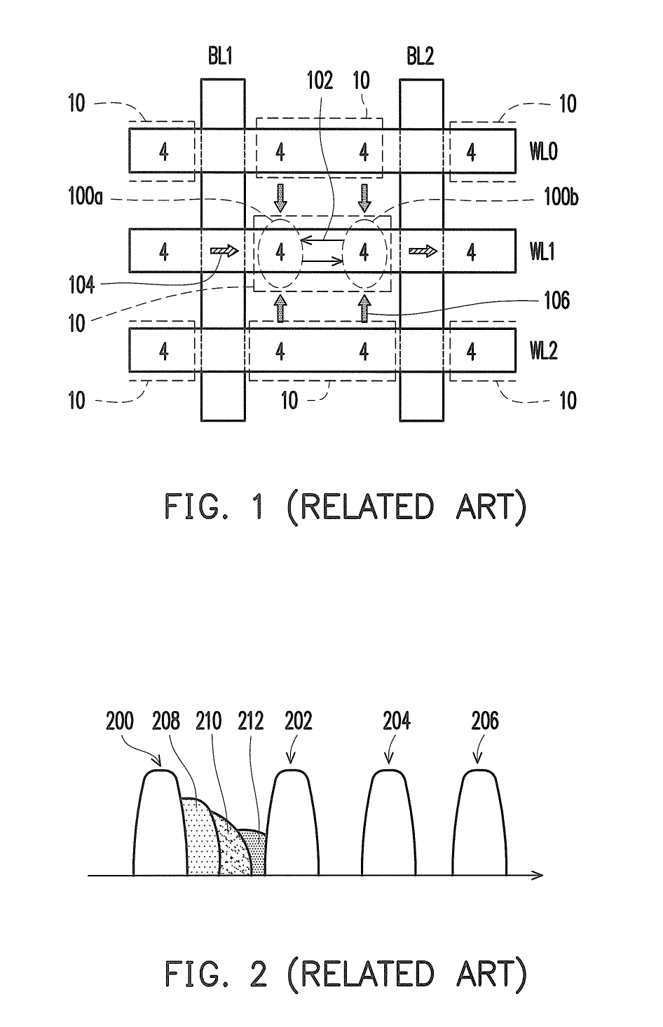

### DESCRIPTION OF EMBODIMENTS

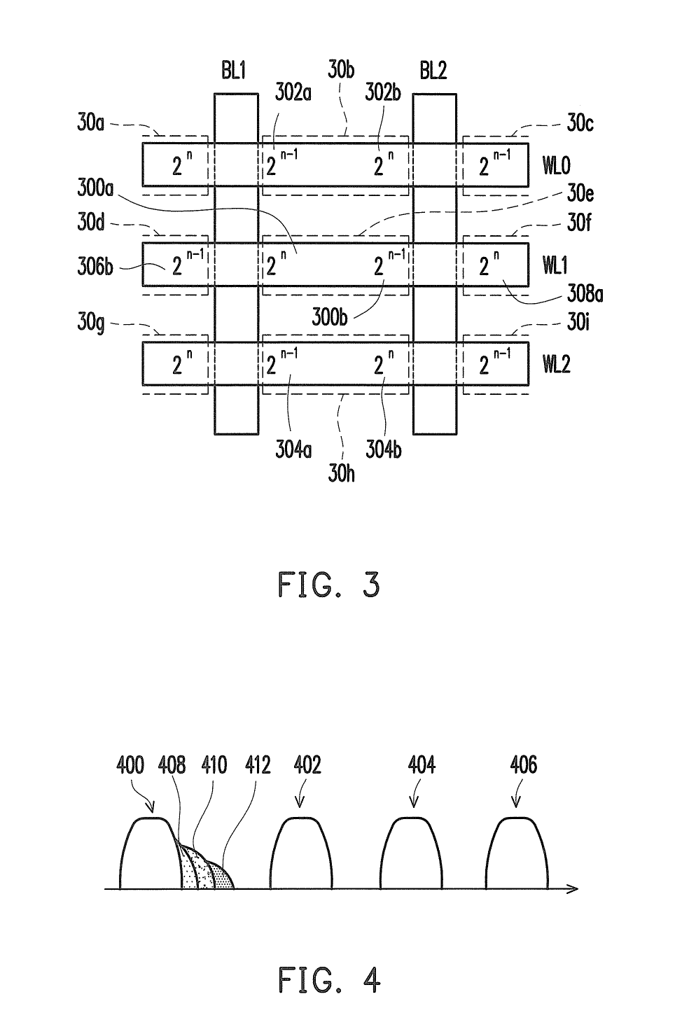

FIG. 3 illustrates a top view of a flash memory according to an embodiment of the invention.

Referring to FIG. 3, the flash memory operation method of this embodiment is configured to operate a flash memory that includes a plurality of memory cells arranged in an array. For instance, the flash memory includes a plurality of word lines including WL0, WL1 and WL2, a plurality of bit lines including BL1 and BL2, and a plurality of charge-trapping cells including 30a-30i. Each of the cells corresponds to one word line and two bit lines, so the flash memory has a virtual ground memory array.

In the operation method of the flash memory, the storage sites (e.g., 306b, 300a, 300b and 308a) in the cells (e.g., 30d, 30e and 30f) coupled to the same word line (e.g., WL1) are set to have 2ⁿ program levels and 2ⁿ⁻¹ program levels alternately, and the storage sites (e.g., 302a, 300a and 304a) in the cells (e.g., 30b, 30e and 30h) coupled to the same bit line (e.g., BL1) are set to have 2ⁿ program levels and 2ⁿ⁻¹ program levels alternately. Each program level corresponds to a different Vt-distribution.

Since a storage site (e.g., 300a) with 2ⁿ program levels is surrounded by storage sites (e.g., 300b, 302a, 304a and 306b) with 2ⁿ⁻¹ program levels in this embodiment, the parasitic effects can be reduced and decrease of the program level number is prevented. Meanwhile, a storage site (e.g., 300b) with 2ⁿ⁻¹ program levels surrounded by storage sites (e.g., 300a, 302b, 308a and 304b) with 2ⁿ program levels can tolerate a larger parasitic capacitance without lowering the program level. In other word, at least a half of the memory cells in the entire flash memory are operated with 2ⁿ program levels. Thereby, the storage density can be increased by 1.5 times as compared to conventional memory in SLC or MLC operation.

In the above embodiment of the invention, n may be a positive integer not less than 2, such as 2, 3 or 4. Thus, the storage site 300a of the memory cell 30e is a multi-level cell (MLC), and the other storage site 300b of the memory cell 30e is a single-level cell (SLC) when n is 2, or a multi-level cell (MLC) when n is 3 or more.

FIG. 4 depicts a Vt-distribution diagram of the storage site 300a when n equals 2, where each of the four program levels corresponds to a different Vt-distribution. Each of the four storage states 400 (zeroth level), 402 (first level), 404 (second level) and 406 (third level) has a Vt-distribution clearly separated from that of one another. Since a storage site (e.g., 300a) having the larger number of program levels (i.e., four program levels) is surrounded by storage sites having the smaller number of program levels (i.e., two program levels), the Vt-distribution 408 caused by 2^{nd} bit effect, the Vt-distribution 410 caused by 2^{nd} bit effect and program disturbance and the Vt-distribution 412 caused by 2^{nd} bit effect, program disturbance and word line interference are all narrower, so that the Vt-distribution of the storage state 400 is maintained separate from that of the next storage state 402.

Moreover, the flash memory operation method can also be applied to an NAND flash memory.

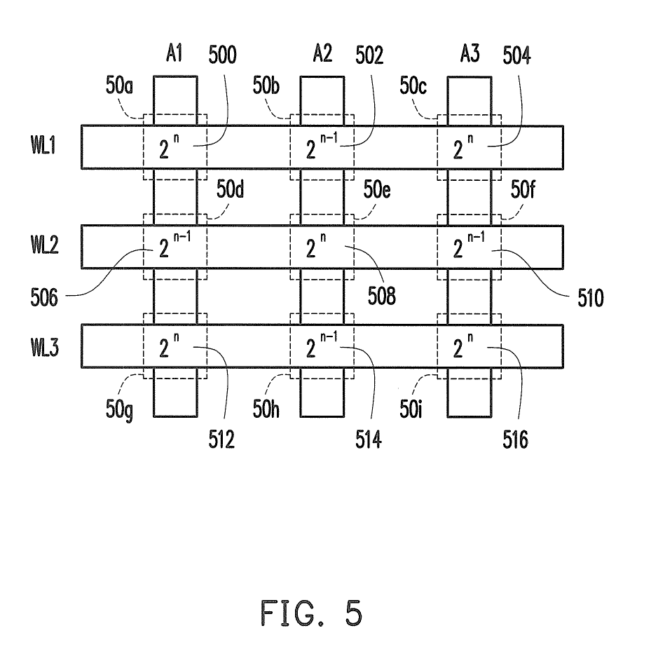

FIG. 5 illustrates a top view of a flash memory according to another embodiment of the invention. Referring to FIG. 5, the operation method of this embodiment is used to operate a flash memory including a plurality of memory cells arranged in an array. For example, the flash memory is an NAND flash memory that includes a plurality of word lines including WL1, WL2 and WL3, a plurality of active areas including A1, A2 and A3, and a plurality of memory cells including 50a-50i. Each of the memory cells is located at the intersection of one word line and one active area, and the memory cells may be charge-trapping memory cells or memory floating-gate cells.

The operation method of this embodiment is described below. When a storage site (e.g., 508) of a cell (e.g., 50e) has 2ⁿ program levels, the number of program levels of the neighboring storage sites (e.g., 502, 506, 510 and 514) is set to 2ⁿ⁻¹. When a storage site (e.g., 502) has 2ⁿ⁻¹ program levels, the number of program levels of the neighboring storage sites (e.g., 500, 504 and 508) is set to 2ⁿ. As a result, when n equals 2, the Vt-distribution of a storage site (e.g., 508) having 2ⁿ program levels in FIG. 5 is the same as that illustrated in FIG. 4.

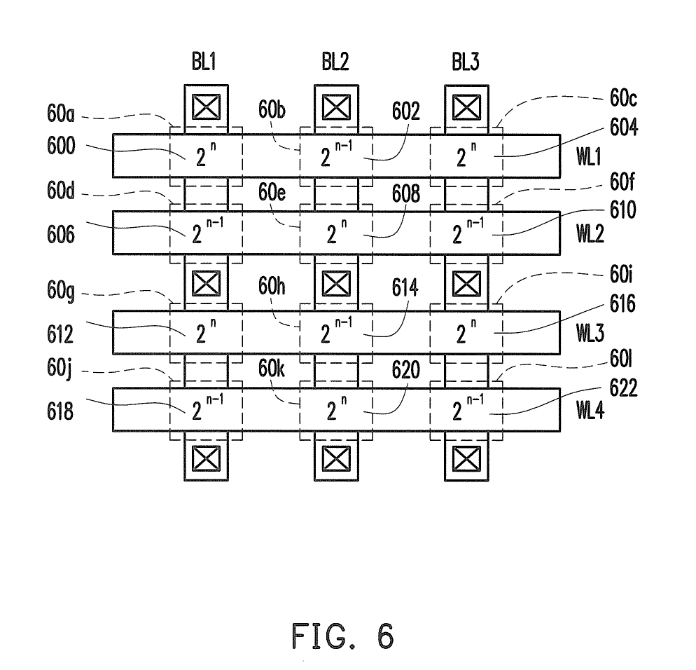

FIG. 6 is a top view of a flash memory according to still another embodiment of this invention. The flash memory includes a plurality of word lines including WL1 to WL4, a plurality of bit lines including BL1 to BL3, and a plurality of floating-gate memory cells including 60a-601. In the layout, each memory cell is a storage site, so the flash memory of this embodiment can also be considered as an NOR floating-gate flash memory array based on a plurality of storage sites 600-622 arranged in an array.

In the operation method of the flash memory shown in FIG. 6, the storage sites (e.g., 600, 602 and 604) corresponding to the same word line (e.g., WL1) are set to have 2ⁿ program levels and 2ⁿ⁻¹ program levels alternately, and the storage sites (e.g., 600, 606, 612 and 618) corresponding to the same bit line (e.g., BL1) are set to have 2ⁿ program levels and 2ⁿ⁻¹ program levels alternately. Each of the program levels corresponds to a different Vt-distribution. In such design, for a storage site (e.g., 608) having the larger number (2ⁿ) of program levels is surrounded by storage sites (e.g., 602, 606, 610 & 614) having the smaller number (2ⁿ⁻¹) of program levels, the Vt-distribution broadening caused by program disturbance and that caused by word-line interference are reduced, so that the Vt-distributions are maintained separate from each other.

In summary, the spirit of the invention is that a storage site having 2ⁿ⁻¹ program levels is surrounded by storage sites having 2ⁿ program levels to prevent decrease in the program level number of storage site. Hence, at least a half of the memory cells in the entire flash memory can be operated with 2ⁿ program levels, and the flash memory has a higher storage density as compared to conventional memory of SLC or MLC operation. Meanwhile, a storage site with the larger number (2ⁿ) of program levels is surrounded by storage sites with the smaller number (2ⁿ⁻¹) of program levels to reduce the parasitic effects, so that the Vt-distributions of the program levels are maintained separate from each other.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method of operating a flash memory that comprises a plurality of storage sites arranged in an array, comprising:
when a first storage site among the storage sites has 2ⁿ program levels, setting numbers of program levels of storage sites neighboring to the first storage site to be 2ⁿ⁻¹; and
when a second storage site among the storage sites has 2ⁿ⁻¹ program levels, setting numbers of program levels of storage sites neighboring to the second storage site to be 2ⁿ,
wherein each of the program levels corresponds to a different threshold voltage distribution.

2. The method of claim 1, wherein the flash memory comprises a virtual ground memory array or an NAND flash memory.

3. The method of claim 1, wherein the flash memory comprises charge-trapping memory cells or floating-gate memory cells.

4. The method of claim 1, wherein the storage sites are multi-level cells (MLC).

5. The method of claim 1, wherein the storage sites comprise multi-level cells (MLC) and single-level cells (SLC).

6. The method of claim 1, wherein n is a positive integer not less than 2.

7. The method of claim 6, wherein n is 2, 3 or 4.

8. A method of operating a flash memory that comprises a plurality of word lines, a plurality of bit lines, and a plurality of memory cells each corresponding to one of the word lines and a pair of bit lines among the plurality of bit lines, comprising:
setting numbers of program levels of a plurality of storage sites of the memory cells corresponding to the same word line to be 2ⁿ and 2ⁿ⁻¹ alternately; and
setting numbers of program levels of a plurality of storage sites of the memory cells corresponding to the same bit line to be 2ⁿ and 2ⁿ⁻¹ alternately,
wherein each of the program levels corresponds to a different threshold voltage distribution.

9. The method of claim 8, wherein the storage sites are multi-level cells (MLC).

10. The method of claim 8, wherein the storage sites comprise multi-level cells (MLC) and single-level cells (SLC).

11. The method of claim 8, wherein n is a positive integer not less than 2.

12. The method of claim 11, wherein n is 2, 3 or 4.

13. The method of claim 8, wherein the flash memory comprises a virtual ground memory array.

14. The method of claim 8, wherein the memory cells comprise charge-trapping memory cells or floating-gate memory cells.
